(19) United States
(12) Patent Application Publication
(10) Pub. No.: US 2008/0278045 A1
(43) Pub. Date: Nov. 13, 2008

(54) CASE ASSEMBLY STRUCTURE OF ELECTRONIC DEVICE

(75) Inventors: Yao-Wen Fan, Taoyuan (TW); Chun Wen, Taoyuan (TW); Chun-Chen Chen, Taoyuan (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan (TW)

(21) Appl. No.: 11/776,400

(22) Filed: Jul. 11, 2007

(30) Foreign Application Priority Data
May 10, 2007 (TW) 096116704

(51) Int. Cl. H05K 5/03

(52) U.S. Cl. 312/223.6

(57) ABSTRACT

The present invention relates to a case assembly structure. The case assembly structure includes a first case and a second case. The first case has a first connection portion including an extension part and a trench from the external side to the internal side thereof. The second case has a second connection portion including a protrusion corresponding to the trench of the first connection portion of the first case. An inner wall of the extension part of the first connection portion is in contact with the external side of the second connection portion of the second case such that the first case and the second case are combined together.

### FIELD OF THE INVENTION

The present invention relates to a case assembly structure, and more particularly to a case assembly structure of an electronic device.

### BACKGROUND OF THE INVENTION

In our daily lives, various electronic devices such as power adapters, transformers, power supply apparatuses, electrical connectors and the like are widely used. Since the internal electronic components and the circuits of these electronic devices need to be appropriately isolated and protected, these electronic devices are usually covered by cases to avoid the contact with the external environment. The assembly structure of the case and the assembling method thereof may indirectly influence the appearances and the electrical properties of the electronic apparatuses or accessories. It is important to design an appropriate case assembly structure.

Referring to FIG. 1, a schematic cross-sectional view of a conventional case assembly structure is illustrated. As shown in FIG. 1, the case assembly structure includes an upper case 1 and a lower case 2. The upper case 1 has a first connection portion 11. Corresponding to the first connection portion 11, the lower case 2 has a second connection portion 21. When the first connection portion 11 and the second connection portion 21 are engaged with each other, the upper case 1 and the lower case 2 are combined together to implement the case assembly structure.

FIG. 2 is a schematic partial enlarged view illustrating the first connection portion 11 of the upper case 1 and the second connection portion 21 of the lower case 2. From the external side 110 to the internal side 111 of the upper case 1, the first connection portion 11 of the upper case 1 includes a first protrusion 112, a first trench 113 and a second protrusion 114. From the external side 210 to the internal side 211 of the lower case 2, the second connection portion 21 of the lower case 2 includes a first concave portion 212, a third protrusion 213 and a second concave portion 214 facing to the first protrusion 112, the first trench 113 and the second protrusion 114 of the first connection portion 11, respectively. In addition, the third protrusion 213 of the second connection portion 21 has a protruding rib 215 thereon, and the width of the third protrusion 213 is slightly smaller than that of the first trench 113 of the first connection portion 11. When the third protrusion 213 of the second connection portion 21 is inserted into the first trench 113 of the first connection portion 11, the upper case 1 and the lower case 2 are combined together.

Please refer to FIGS. 3(a) and 3(b), which are schematic cross-sectional views showing the assembling process of the case assembly structure in FIG. 2. As shown in FIG. 3(a), for assembling the upper case 1 and the lower case 2, the first protrusion 112, the first trench 113 and the second protrusion 114 of the upper case 1 are firstly placed to face to the first concave portion 212, the third protrusion 213 and the second concave portion 214 of the lower case 2, respectively. Then, according to an ultrasonic welding technology, the ultrasound generated by the horn of an ultrasonic plastic welding machine produces ultra-frequent sonic vibration on the cases. Under this circumstance, the upper case 1 and the lower case 2 rub against each other violently and thus the protruding rib 215 on the third protrusion 213 of the lower case 2 can be molten and welded into the inner wall of the first trench 113 of the upper case 1 in a very short time, as can be seen in FIG. 3(b). Meanwhile, the purpose of assembling the upper case 1 and the lower case 2 is achieved.

However, no matter what case assembling process is adopted, the upper case 1 and the lower case 2 are produced by plastic injection molding. As known, the products made from plastic injection molding usually have disadvantages of fracture, shade or flow mark, lack of gloss, or deformation and so on. The reason that causes the formation of flow mark on the product of plastic injection molding includes: the material is not sufficiently molten; the temperature of the mode is too low; the injection rate is too fast or too slow; the injection pressure is too high or too low; or the thickness difference on the cross-section of the product is too large. Whereas, the reason that causes the formation of shade on the product is the wall thickness of the connection portion of the case is uneven. Since the shade or flow mark may impair the appearance of the case assembly structure, how to reduce the formation of shade or flow mark becomes an important issue.

Please refer to FIG. 2 again. From the external side 110 to the internal side 111 of the upper case 1 of the conventional case assembly structure, the thickness difference on the cross-section of the first connection portion 11 of the upper case 1 is too large or the wall thickness of the first connection portion 11 of the upper case 1 is uneven due to the level difference between the first protrusion 112 and the first trench 113. Therefore, after the upper case 1 is injection molded, the shade or flow mark 120 may be formed on the external side 110 of the first connection portion 11. As the level difference between the first protrusion 112 and the first trench 113 is increased, the range of the shade or flow mark 120 is broadened. When the upper case 1 and the lower case 2 are assembled, the obvious shade or flow mark 120 will be formed on the external side of the case.

In addition, after the upper case 1 and the lower case 2 are assembled, the creepage distance formed between the connection portions 11 and 21 is not long enough. As a consequence, the electric leakage may occur, which indirectly influence the electric properties of the electronic device. Moreover, since the bonding strength between the upper case 1 and the lower case 2 is insufficient, the electronic device fails to withstand a stronger impact. For solving these drawbacks, the thicknesses of the connection portions 11 and 21 need to be greater than 3 mm, which increases material consumption. Moreover, for increasing the creepage distance, the length of the second protrusion 114 of the first connection portion 11 should be long enough. In a case that an external force perpendicular to the external sides of the connection portions 11 and 21, the second protrusion 114 or even the case assembly structure is readily fractured due to the structural fragility.

Therefore, there is a need of providing a case assembly structure having decreased formation of shade or flow mark and increased creepage distance and the bonding strength so as to overcome the disadvantages of the prior art as described above.

### SUMMARY OF THE INVENTION

It is an object of the present invention to provide a case assembly structure having decreased formation of shade or flow mark and increased creepage distance and the bonding strength, thereby improving the case appearance and the electric properties of the electronic device.

Another object of the present invention provides a case assembly structure having reduced thickness and material cost without impairing the bonding strength between the upper case and the lower case.

In accordance with an aspect of the present invention, there is provided a case assembly structure of an electronic device. The case assembly structure includes a first case and a second case. The first case has a first connection portion including an extension part and a trench from the external side to the internal side thereof. The second case has a second connection portion including a protrusion corresponding to the trench of the first connection portion of the first case. An inner wall of the extension part of the first connection portion is in contact with the external side of the second connection portion of the second case such that the first case and the second case are combined together.

In accordance with another aspect of the present invention, there is provided a case assembly structure of an electronic device. The case assembly structure includes a first case and a second case. The first case has a first connection portion including an extension part and a trench from the external side to the internal side thereof. An entrance is defined by the inner wall of the extension part of the first case. The second case has a second connection portion including a protrusion corresponding to the trench of the first connection portion of the first case. The second case is embedded into the entrance of the first case such that the first case and the second case are combined together.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view of a conventional case assembly structure;

FIG. 2 is a schematic partial enlarged view illustrating the first connection portion of the upper case and the second connection portion of the lower case;

FIGS. 3(a) and 3(b) are schematic cross-sectional views showing the assembling process of the case assembly structure in FIG. 2;

FIG. 4 is a schematic cross-sectional view of a case assembly structure according to a preferred embodiment of the present invention;

FIG. 5 is a schematic perspective view of the case assembly structure in FIG. 4;

FIG. 6 is a schematic partial enlarged view illustrating the first connection portion of the first case and the second connection portion of the second case;

FIG. 7 is a schematic partial enlarged view illustrating a variant embodiment of the first connection portion of the first case and the second connection portion of the second case; and

FIGS. 8(a) and 8(b) are schematic cross-sectional views showing the assembling process of the case assembly structure in FIG. 6.

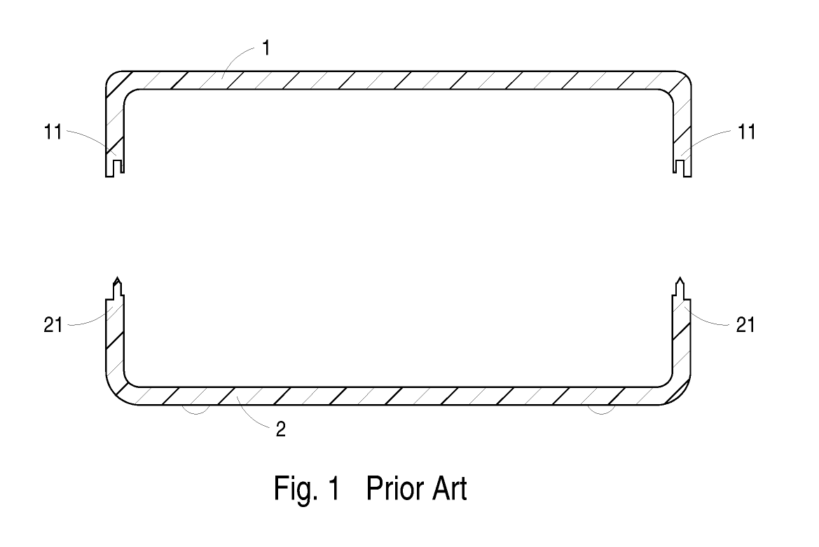

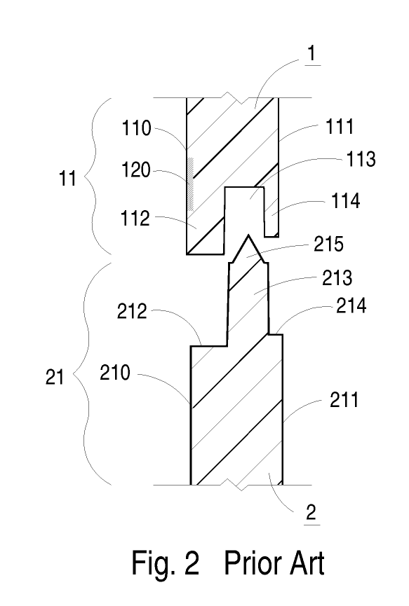

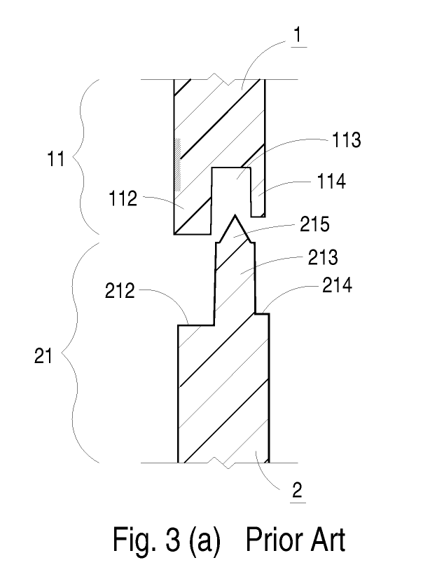

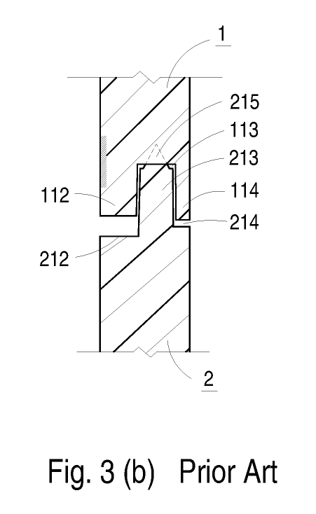

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

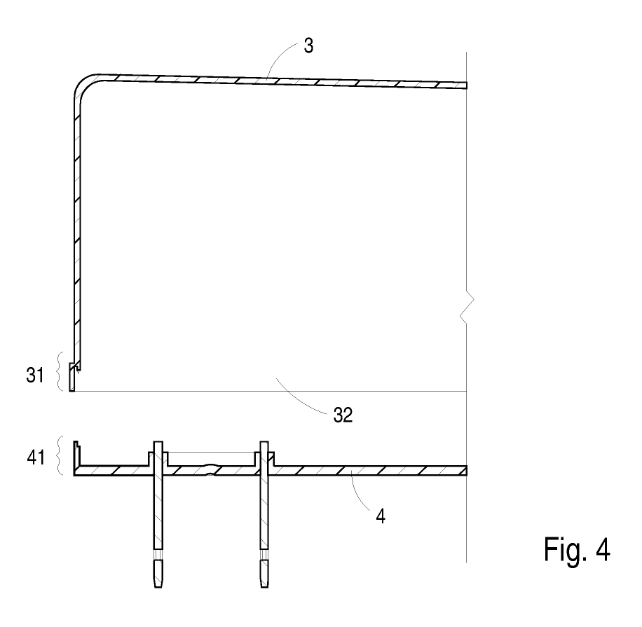

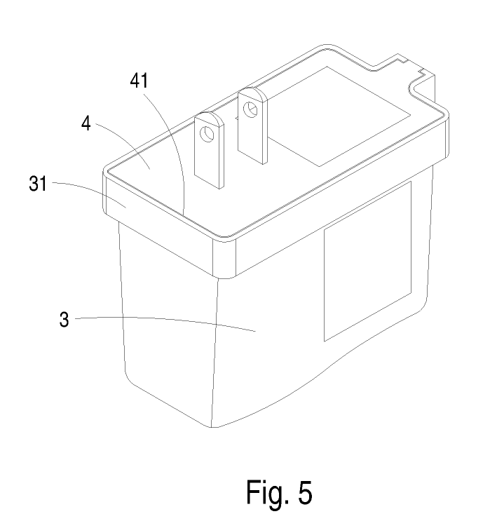

Referring to FIG. 4, a schematic cross-sectional view of a case assembly structure according to a preferred embodiment of the present invention is illustrated. As shown in FIG. 4, the case assembly structure includes a first case 3 and a second case 4. The first case 3 has a first connection portion 31. Corresponding to the first connection portion 31, the second case 4 has a second connection portion 41. When the first connection portion 31 and the second connection portion 41 are engaged with each other, the first case 3 and the second case 4 are combined together to implement the case assembly structure. In some embodiments, the first case 3 and the second case 4 are a box and a lid, respectively. The first case 3 has an entrance 32 mating with the external side of the second case 4. When the second case 4 is embedded into the entrance 32 of the first case 3, the first case 3 and the second case 4 are combined together to form a case assembly structure as shown in FIG. 5.

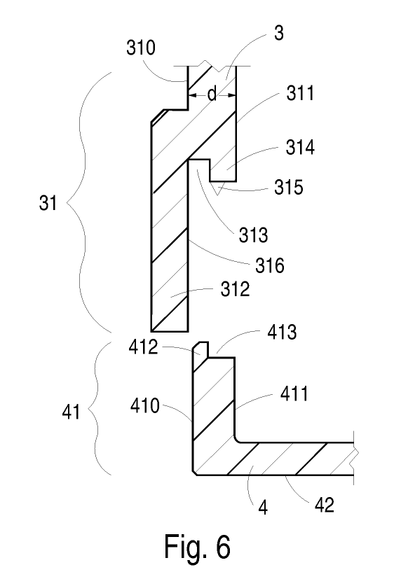

FIG. 6 is a schematic partial enlarged view illustrating the first connection portion 31 of the first case 3 and the second connection portion 41 of the second case 4. From the external side 310 to the internal side 311 of the first case 3, the first connection portion 31 of the first case 3 includes an extension part 312, a trench 313 and a convex part 314. From the external side 410 to the internal side 411 of the second case 4, the second connection portion 41 of the second case 4 includes a protrusion 412 and a concave part 413. The protrusion 412 and the concave part 413 of the second case 4 are opposite to the trench 313 and the convex part 314 of the first case 3. The width of the protrusion 412 of the second case 4 is slightly smaller than that of the trench 313 of the first case 3. Furthermore, the extension part 312 is extended outward the external side 310 of the first connection portion 31 of the first case 3. The extension part 312 is substantially parallel to the external side 310 of the first connection portion 31. The entrance 32 is defined by the inner wall 316 of the extension part 312 of the first case 3. In this embodiment, the second case 4 is tight-fitted into the entrance 32 of the first case 3. That is, the inner wall 316 of the extension part 312 is in close contact with the external side 410 of the second connection portion 41 of the second case 4. When the second case 4 is tight-fitted into the entrance 32 of the first case 3, the tip of the extension part 312 is substantially at the same level with the bottom surface 42 of the second case 4.

In some embodiments, the convex part 314 of the first case 3 has a protruding rib 315 thereon. According to an ultrasonic welding technology, the protruding rib 315 on the convex part 314 of the first case 3 may be molten and welded (or implanted) into the inner wall of the concave part 413 of the second case 4, so that the first case 3 and the second case 4 are combined together.

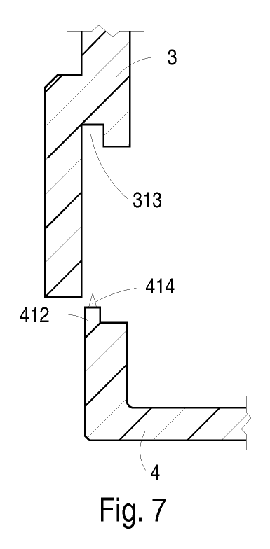

It is noted that, however, those skilled in the art will readily observe that numerous modifications and alterations of the protruding rib may be made while retaining the teachings of the invention. For example, as shown in FIG. 7, the protrusion 412 has a protruding rib 414 thereon. Likewise, according to an ultrasonic welding technology, the protruding rib 414 on the protrusion 412 of the second case 4 may be molten and welded into the inner wall of the trench 313 of the first case 3, so that the first case 3 and the second case 4 are combined together.

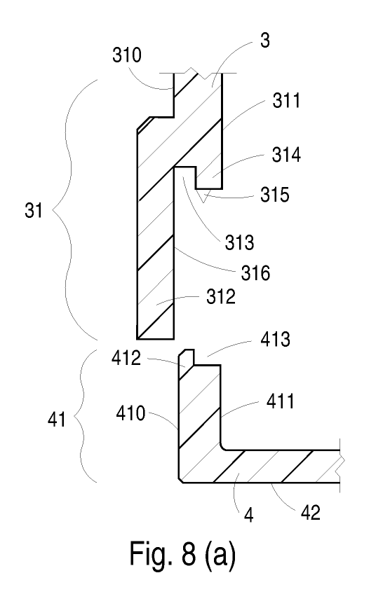

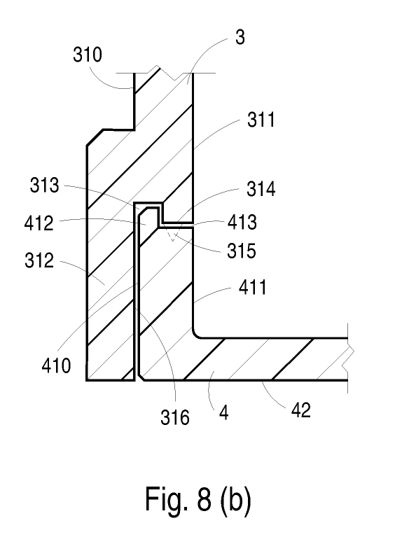

Please refer to FIGS. 8(a) and 8(b), which are schematic cross-sectional views showing the assembling process of the case assembly structure in FIG. 6. As shown in FIG. 8(a), for assembling the first case 3 and the second case 4, the trench 313 and the convex part 314 of the first case 3 are firstly placed to face to the protrusion 412 and the concave part 413 of the second case 4, respectively. Then, the second case 4 is inserted into the entrance 32 of the first case 3 such that the inner wall 316 of the extension part 312 is in close contact with the external side 410 of the second connection portion 41 of the second case 4. Then, according to an ultrasonic welding technology, the ultrasound generated by the horn of an ultrasonic plastic welding machine produces ultra-frequent sonic vibration on the cases. Under this circumstance, the first case 3 and the second case 4 rub against each other violently and thus the protruding rib 315 on the convex part 314 of the first case 3 will be molten and welded into the inner wall of the concave part 413 of the second case 4 in a very short time, as can be seen in FIG. 8(b). Meanwhile, the purpose of assembling the first case 3 and the second case 4 is achieved.

In the above embodiments, the first case 3 and the second case 4 are combined together by the ultrasonic welding technology. It is noted that, however, those skilled in the art will readily observe that numerous modifications and alterations of the assembling method may be made while retaining the teachings of the invention. For example, if the protruding rib 315 on the convex part 314 of the first case 3 is dispensed, the first connection portion 31 of the first case 3 and the second connection portion 41 of the second case 4 may be tight-fitted. Alternatively, the first case 3 and the second case 4 may be combined together via adhesive. Alternatively, the first case 3 and the second case 4 may be combined together by screwing or fastening means.

As previously described, the conventional case assembly structure is disadvantageous for the uneven wall thickness of the connection portion and the large thickness difference on the cross-section. Whereas, as shown in FIG. 6, the case assembly structure of the present invention has more even wall thickness of the connection portion and smaller thickness difference on the cross-section from the external side to the internal side. As a consequence, it is difficult to form shade or flow mark on the external side 310 of the first case 3 or the external side 310 of the second case 3 when the first case 3 and the second case 4 are injection molded. No matter what assembling process (e.g. ultrasonic welding, adhering, fastening or screwing means) is adopted, the case assembly structure of the present invention has minimized shade or flow mark. Moreover, after the first case 3 and the second case 4 are assembled, the creepage distance formed between the connection portions 31 and 41 is obviously extended due to the extension part 312 of the first case 3. As the creepage distance is increased, the electric properties are enhanced. Since the inner wall 316 of the extension part 312 is in close contact with the external side 410 of the second connection portion 41 of the second case 4 and the second case 4 is inserted into the entrance 32 of the first case 3, the bonding strength between the first case 3 and the second case 4 is largely enhanced. In a case that an external force perpendicular to the external side 310 of the first connection portion 31 of the first case 3, the second case 4 may facilitate the extension part 312 of the first case 3 to withstand a strong impact. Moreover, since the length of the convex part 314 of the first case 3 is reduced, the possibility of causing fracture at the convex part 314 will be minimized.

Please refer to FIG. 6 again. The extension part 312 is extended outward the external side 310 of the first connection portion 31 of the first case 3 and substantially parallel to the external side 310 of the first connection portion 31. The thickness d of the first case 3 may be kept below 2 mm without impairing the structural strength of the case assembly structure. As a consequence, the case assembly structure of the present invention has less material consumption when compared with the prior art.

From the above description, the case assembly structure of the present invention has specific profiles on the connection portions of the first case and the second case. By means of these specific profiles, the formation of shade or flow mark is decreased during the injection molding process. In addition, the case assembly structure of the present invention has an increased creepage distance, excellent electric properties and enhanced structural strength without additional material consumption.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A case assembly structure of an electronic device, comprising:
a first case having a first connection portion including an extension part and a trench from the external side to the internal side thereof; and
a second case having a second connection portion including a protrusion corresponding to said trench of said first connection portion of said first case, wherein an inner wall of said extension part of said first connection portion is in contact with the external side of said second connection portion of said second case such that said first case and said second case are combined together.

2. The case assembly structure according to claim 1 wherein said first connection portion of said first case includes said extension part, said trench and further a convex part from the external side to the internal side thereof, and said second connection portion of said second case includes said protrusion and further a concave part, said concave part of said second case being opposite to said convex part of said first case.

3. The case assembly structure according to claim 2 wherein said first connection portion of said first case further includes a protruding rib on said convex part, wherein said protruding rib is implanted into the inner wall of said concave part of said second case when said first case and said second case are combined together.

4. The case assembly structure according to claim 2 wherein said second connection portion of said second case further includes a protruding rib on said protrusion, wherein said protruding rib is implanted into the inner wall of said trench of said first case when said first case and said second case are combined together.

5. The case assembly structure according to claim 2 wherein the width of said protrusion of said second case is slightly smaller than that of said trench of said first case.

6. The case assembly structure according to claim 1 wherein said first case and said second case are combined together by an ultrasonic welding technology.

7. The case assembly structure according to claim 1 wherein said extension part is extended outward the external side of said first connection portion of said first case, and substantially parallel to the external side of the said first connection portion.

8. The case assembly structure according to claim 1 wherein said first case and said second case are a box and a lid, respectively.

9. The case assembly structure according to claim 1 wherein an entrance is defined by the inner wall of said extension part of said first case, and said second case is embedded into said entrance of said first case.

10. The case assembly structure according to claim 9 wherein a tip of said extension part is substantially at the same level with the bottom surface of said second case when said second case is embedded into said entrance of said first case.

11. A case assembly structure of an electronic device, comprising:
a first case having a first connection portion including an extension part and a trench from the external side to the internal side thereof, wherein an entrance is defined by the inner wall of said extension part of said first case; and
a second case having a second connection portion including a protrusion corresponding to said trench of said first connection portion of said first case, wherein said second case is embedded into said entrance of said first case such that said first case and said second case are combined together.

12. The case assembly structure according to claim 11 wherein said first connection portion of said first case includes said extension part, said trench and further a convex part from the external side to the internal side thereof, and said second connection portion of said second case includes said protrusion and further a concave part, said concave part of said second case being opposite to said convex part of said first case.

13. The case assembly structure according to claim 12 wherein said first connection portion of said first case further includes a protruding rib on said convex part, wherein said protruding rib is implanted into the inner wall of said concave part of said second case when said first case and said second case are combined together.

14. The case assembly structure according to claim 12 wherein said second connection portion of said second case further includes a protruding rib on said protrusion, wherein said protruding rib is implanted into the inner wall of said trench of said first case when said first case and said second case are combined together.

15. The case assembly structure according to claim 12 wherein the width of said protrusion of said second case is slightly smaller than that of said trench of said first case.

16. The case assembly structure according to claim 11 wherein said first case and said second case are combined together by an ultrasonic welding technology.

17. The case assembly structure according to claim 11 wherein said extension part is extended outward the external side of said first connection portion of said first case, and substantially parallel to the external side of the said connection portion.

18. The case assembly structure according to claim 11 wherein said first case and said second case are a box and a lid, respectively.

19. The case assembly structure according to claim 11 wherein an inner wall of said extension part of said first connection portion is in contact with the external side of said second connection portion of said second case.

20. The case assembly structure according to claim 11 wherein a tip of said extension part is substantially at the same level with the bottom surface of said second case when said second case is embedded into said entrance of said first case.
